(19) United States
(12) Patent Application Publication
(10) Pub. No.: US 2004/0059992 A1
(43) Pub. Date: Mar. 25, 2004

(54) Methods of optimizing the decoding of signals based on a complete majority logic representation

(76) Inventor: Keng Tiong Tan, Hong Kong (HK)

Correspondence Address: SWIDLER BERLIN SHEREFF FRIEDMAN, LLP, 3000 K STREET, NW, BOX IP, WASHINGTON, DC, 20007, US

(21) Appl. No.: 10/461,514

(22) Filed: Jun. 16, 2003

Related U.S. Application Data
(60) Provisional application No. 60/388,737, filed on Jun. 17, 2002.

(51) Int. Cl. H03M 13/03

(52) U.S. Cl. 714/795

(57) ABSTRACT

A method and apparatus for optimizing signal detection, multiplexing and de-multiplexing with error correction coding, artificial neural network signal processing, and combination of linear and non-linear coding/decoding scheme is disclosed which is only possible with the disclosure of the method to completely derive the multinomial representation of hard threshold non-linear summation functions of arbitrary binary inputs. The method of deriving the complete multinomial representation of these hard threshold non-linear summation functions of arbitrary binary inputs are not previously known and the ability to derive these multinomial function allowed for the optimization of the signal processing in the aforementioned applications, and other applications using such types of hard threshold non-linear summation functions of arbitrary binary inputs.

### CROSS-REFERENCE TO PENDING APPLICATION

This application makes reference to an invention detailed in a pending U.S. provisional patent application entitled “Methods of Optimizing the Decoding of Signals based on a Complete Majority Logic Representation” filed on Jun. 17, 2002 (attached hereto as Appendix A) and referred to as the provisional patent application and provisional patent filing.

### FIELD OF THE INVENTION

The present invention relates generally to the optimum decoding of signals based on a complete majority logic representation and, more specifically, to using the complete majority logic representation in applications in the areas of, but not restricted to, signal hard threshold detection, signal multiplexing and de-multiplexing, signal processing in artificial neural networks, and combined linear and non-linear signal coding and decoding.

### BACKGROUND OF THE INVENTION

Conventionally, majority logic and other comparable non-linear functions for the sum of binary data, such as the sigmodial functions used in artificial neural networks, are considered hard threshold or input squashing/activation functions because these non-linear functions render their inputs into fixed output ranges. In many cases, signal decoding based on such hard threshold non-linear functions results in a loss of signal energy which reduces their effectiveness for certain applications. In other cases, such hard threshold non-linear functions are discontinuous and non-differentiable, thus, rendering them less useful for use as squashing/activation functions for artificial neural networks.

By way of definition, a function is differentiable if the right hand side of the equation in the function is a variable of which the function is differentiated against. For example, y=x is differentiable by x, where

$$\frac{ⅆ y}{ⅆ x} = 1 ,$$

but y=1 is non-differentiable as the right hand side of the equation is a constant number. A function is continuous, if and only if, there exist a value for the function throughout the entire range of the function. For example, if a function has a range between −1 and +1, then the function is continuous if it exists for all values between the extremities of −1 and +1.

Consider the following non-linear functions for the sum of binary data. One such typical non-linear hard threshold function is the sign function, where

$$sign ( x ) := \{ \begin{matrix}1 & if & x > 0 \\ 0 & if & x = 0 \\ - 1 & if & x < 0\end{matrix} , \qquad ( 1.1 )$$

where x is the input signal, or, sum of n input signals when

$$x = {\sum }_{i = 1}^{n} {x}_{i} .$$

Alternatives to the sign function in (1.1) are

$$\begin{matrix} {sign}_{+} ( x ) := \{ \begin{matrix}1 & if & x > 0 \\ 1 & if & x = 0 \\ - 1 & if & x < 0\end{matrix} , \\ and & ( 1.2 ) \\ {sign}_{-} ( x ) := \{ \begin{matrix}1 & if & x > 0 \\ - 1 & if & x = 0 \\ - 1 & if & x < 0\end{matrix} . & ( 1.3 )\end{matrix}$$

From the non-linear functions in (1.1), (1.2) and (1.3), the following is apparent:

These non-linear hard threshold functions can take in an arbitrary sum of inputs but produce only outputs in two or three discreet fixed values.

For a given sum of arbitrary inputs, which can be greater or less than the fixed output values of the non-linear hard threshold functions, the output of these functions is always one of the two or three discreet fixed values. Hence, this results in a loss in signal information and energy.

These non-linear hard threshold functions are non-continuous and non-differentiable (due to the fact that the output of these functions is not a variable of their inputs). For example, in (1.2) the output of sign₊(x) is an integer of value +1 or −1, which is not a function of x.

Because of the loss in signal information and energy, any signal passed thorough a hard threshold function would constitute a hard decision being made. In communications systems and information theory, a hard decision process is generally regarded as a process where signal energy up to 2 decibels is loss compared to a soft decision process. A soft decision process is where no hard threshold function is applied on the given input or sum of input signals. It is because of this difference in detected signal information and energy that soft decision signal decoding is usually the preferred option over hard decision signal decoding, although the latter usually requires simpler hardware architecture.

The non-linear sign function may be used to multiplex and de-multiplex more than one channel of data for transmission. For example, in some prior patent filings by the inventor of the current patent filing, namely patent filings entitled “Method and apparatus for non-linear code-division multiple access technology”, “Method and apparatus for non-linear code-division multiple access technology with improved detection algorithms and error correction coding” and “Method and apparatus for spread spectrum communication systems using non-linear code words”, the non-linear functions sign and sign_{±} have been used in coding schemes which encompass spread spectrum spreading and error corrections in wireless communication systems.

In artificial neural networks, the most natural representation of an squashing/activation function in a neural cell is the “0-1 step” function. A “0-1 step” function is a representation of the sign function within the domain of binary {0,1}. A “0-1 step” function is

$$sign ( x ) := \{ \begin{matrix}1 & if & x > 0 \\ 0 & if & x < 0\end{matrix} . \qquad ( 1.4 )$$

From (1.4) we can see that a “0-1 step” function is the same as the sign function of (1.1) except for the case where x=0 is undefined. In artificial neural networks, it is required to calculate the gradient of the squashing/activation function at each iteration step of the learning process. Therefore, the squashing/activation function must be continuous and differentiable. However, because of the discontinuity and the fact the sign function as represented in (1.4) is not differentiable, the sign function not suitable for implementations of artificial neural networks. Alternative squashing/activation functions such as the sigmodial function are used instead. A sigmodial function is defined as

$$sigmodial ( x ) = \frac{1}{1 + {ⅇ}^{ c x}} , \qquad ( 1.5 )$$

where c is a constant determining the slope of the sigmodial function. This function is continuous and differentiable. However, the trade off is that the use of such sigmodial squashing/activation function may result in cases where local minima appear where they did not for the cases using a “0-1 step” as the squashing/activation function. Over the years a variety of different learning algorithms have been developed with the objective of reaching the global minima in the quickest time, and avoiding, if possible, the appearance of local minima.

In the context of artificial neural networks, a squashing/activation function is the function responsible for turning the input signals going into an artificial neural network neuron into the decision signal transmitted from the output of the same neuron.

Prior to the referenced provisional patent filing, entitled “Methods of Optimizing the Decoding of Signals based on a Complete Majority Logic Representation”, the sign function in (1.1) was represented in multinomial form as

$$\begin{matrix}sign ( {\sum }_{i = 1}^{n} {x}_{i} ) = {ρ}_{1} {\sum }_{i = 1}^{n} {x}_{i} + {ρ}_{2} {\sum }_{all i > j} {x}_{i} {x}_{j} + … + {ρ}_{n} {\sum }_{i = 1}^{n} {x}_{i} , \\ where & ( 1.6 ) \\ {ρ}_{1} = \{ \begin{matrix}{2}^{1 - n} ( \begin{matrix}n - 1 \\ \frac{n - 1}{2}\end{matrix} ) , if n is odd , \\ {2}^{- n} ( \begin{matrix}n \\ \frac{n}{2}\end{matrix} ) , if n is even , \end{matrix} \\ and & ( 1.7 ) \\ {ρ}_{n} = \{ \begin{matrix}- {ρ}_{1} & if n + 1 is a multiple of 4 , \\ {ρ}_{1} & if n + 1 is not a multiple of 4 ,\end{matrix} \\ and & ( 1.8 ) \\ \vert {ρ}_{i} \vert < {ρ}_{1} for i = 2 , 3 , … , n - 1. & ( 1.9 )\end{matrix}$$

Also conventionally, for all odd values of n, all ρᵢ with even subscripts were said to vanish.

Therefore, the conventional multinomial representation for the sign function of(1.1) is incomplete. The equations from (1.6) to (1.9) are incomplete because of the following missing elements:

1. We only know that (1.6) exists for the sign function of(1.1) and not other similar types of non-linear functions;

2. From (1.7) to (1.9), we only know about how to derive the values of the coefficients for ρᵢ and ρₙ, but not for all the other coefficients ρᵢ, where i={0, 2, 3, . . . , n−1};

3. We do not know the values for all the coefficients ρᵢ, where i={0, 2, 3, . . . , n−1}, in all cases for both odd and even values of n;

Because the conventional multinomial representation of the non-linear sign function was incomplete, its actual use in hard threshold decoding, data signals multiplexing and de-multiplexing, and better artificial neural network squashing/activation functions has been limited or non-existent.

Prior to the disclosure of the provisional patent application filing the complete multinomial representation of a non-linear function such as that of (1.1), and others such as (1.2) and (1.3), and the sigmodial function of (1.5) was unknown.

Accordingly, there is a need for a complete multinomial representation of non-linear functions such as the sign function, the sigmodial function and others such as equations 1.2 and 1.3. There is a further need to improve decoders, artificial neural networks and other systems by implementing non-linear functions within systems that are based on a complete multinomial representation.

### SUMMARY OF THE INVENTION

According to the present invention, the complete multinomial representation of all the aforementioned non-linear functions given as

$$\begin{matrix}sign * ( {\sum }_{i = 1}^{n} {x}_{i} ) = {ρ}_{0} + {ρ}_{1} {\sum }_{i = 1}^{n} {x}_{i} + {ρ}_{2} {\sum }_{all i > j} {x}_{i} {x}_{j} + \\ {ρ}_{3} {\sum }_{all i > j > k} {x}_{i} {x}_{j} {x}_{k} + … + {ρ}_{n} {\sum }_{i = 1}^{n} {x}_{i} ,\end{matrix} \qquad ( 1.10 )$$

where * ∈{+, −, }, as (1.10) represents more than just the typical sign non-linear function.

To reinforce an important point at this juncture, the embodiments of the present invention are based on the complete derivation of the multinomial representation of non-linear functions of (1.1), (1.2), (1.3), (1.4), (1.5) and any functions for sum of arbitrary binary input data can be represented in a complete multinomial representation, as shown in(1.10). Unlike the incomplete multinomial representation of (1.6) given in the prior art, the invention presented in the referenced provisional patent also details the complete derivation of the ρᵢ, where i=0, 1, 2, . . . , n, for all the aforementioned non-linear functions, for both odd and even values of n.

According to one embodiment of the present invention, an improved signal detection scheme using the non-linear hard threshold functions is proposed, where there is no, or very little loss in received signal energy or information.

In yet another embodiment of the present invention, a signal coding, multiplexing, and de-multiplexing, iterative decoding scheme using concatenated block and convolutional or Turbo codecs, together with spread spectrum spreading is proposed.

In another embodiment of the present invention, a differentiable signal squashing/activation function for the use in artificial neural networks based on the non-linear threshold sign function is proposed.

In a further embodiment of the present invention, a method of coding and decoding of signals comprising of the derivation for the parity bits for the composite signal, coding the parity bits based on a linear coding function, followed by the coding of the composite signal and its parity bits based on a non-linear hard threshold function, and transmission of the resultant coded signal, for decoding at the receiver end, which entails both the non-linear function and a linear decoding function.

### BRIEF DESCRIPTION OF THE FIGURES

The above described features and advantages of the present invention will be more fully appreciated with reference to the detailed description and appended figures, in which:

FIG. 1 depicts a flow diagram depicting the use of multinomial representation of non-linear hard threshold functions to improve the detection of a “hard decision” signal detection scheme.

FIG. 2 depicts a block diagram depicting an embodiment of the present invention, where the multinomial representation of a non-linear function is used in a data signal multiplexing/de-multiplexing together with serially concatenated error correction decoding.

FIG. 3 depicts a ⅓ Turbo encoder for an example in the implementation of a data signal multiplexing/de-multiplexing together with serially concatenated error correction decoding.

FIG. 4 depicts a block diagram example of the transmitter in the example in the implementation of a data signal multiplexing/de-multiplexing together with serially concatenated error correction decoding.

FIG. 5 depicts a block diagram example of the receiver in the example in the implementation of a data signal multiplexing/de-multiplexing together with serially concatenated error correction decoding.

FIG. 6 is a flow diagram depicting the use of multinomial representation of non-linear hard threshold functions in deriving an improved signals multiplexing and de-multiplexing scheme with a serially concatenated iterative decoding architecture.

FIG. 7 is a flow diagram depicting the use of multinomial representation of non-linear hard threshold functions as artificial neural network squashing/activation functions.

FIG. 8 is a flow diagram depicting the use of multinomial representation of non-linear hard threshold functions in a novel combination of linear and non-linear coding and decoding functions for signal communication.

FIG. 9 is a flow chart depicting the steps taken in the complete derivation of the multinomial representation of the non-linear functions utilized in this patent.

### DETAILED DESCRIPTIONS

I. Overview

The complete majority logic representation of equations such as 1.1, 1.2, 1.3 and 1.5, set forth in the summary of the invention section, is further described below applied in applications for better signal detection, signal multiplexing and coding, together with de-multiplexing and iterative decoding, use in improvements for artificial neural networks signal processing, and finally, a novel combined linear and non-linear signal coding and decoding scheme.

II. A “Hard Decision” Signal Detection Scheme Using the Multinomial Representation of the Non-linear Hard threshold Functions

An embodiment of the present invention is a hard decision based signal detection scheme that exploits the multinomial representation of the non-linear hard threshold functions of (1.1), (1.2), (1.3), (1.4), (1.5) and any functions for sum of arbitrary binary input data can be represented in a complete multinomial representation.

To illustrate this embodiment, we shall take the example of hard threshold signal decoding for 3 parallel streams of bipolar data α, β and γ, multiplied to 3 mutually orthogonal signals, namely, x1, x2 and x3, where

x1=[1 −1 1 −1];

x2=[1 1 −1 −1]; (1.11)

x3=[1 −1 −1 1];

and the signal to be received after transmission through a channel is

x=α·x1+β·x2+γ·x3+N, (1.12)

where N is noise in the system.

The conventional “hard decision” approach to decoding the received signal x in (1.12) is

$$\begin{matrix}\begin{matrix}\hat{α} = sign ( {\int }_{{t}_{0}}^{{t}_{3}} x1 \cdot x \partial t ) ; \\ \hat{β} = sign ( {\int }_{{t}_{0}}^{{t}_{3}} x2 \cdot x \partial t ) ;\end{matrix} \\ \hat{γ} = sign ( {\int }_{{t}_{0}}^{{t}_{3}} x3 \cdot x \partial t ) ;\end{matrix} \qquad ( 1.13 )$$

where t₀ to t₃ represents the bit timing of the orthogonal signature bit patterns of x1, x2 and x3, and, \hat{α}, \hat{β} and \hat{γ} being the estimated values of the transmitted data α, β and γ. a·b is arithmetic dot product of a and b. With (1.13), signal is lost when the hard threshold sign function is used to determine the estimated values for α, β and γ. If a hard threshold decision must be made of the received signal x in (1.12), then a better approach in hard threshold decoding is

x′=sign(x), (1.14)

and,

$$\begin{matrix}\begin{matrix}\hat{α} = {\int }_{{t}_{0}}^{{t}_{3}} x1 \cdot {x}^{′} \partial t ; \\ \hat{β} = {\int }_{{t}_{0}}^{{t}_{3}} x2 \cdot {x}^{′} \partial t ;\end{matrix} \\ \hat{γ} = {\int }_{{t}_{0}}^{{t}_{3}} x3 \cdot {x}^{′} \partial t ; \\ \cdot \hat{β} \cdot γ = {\int }_{{t}_{0}}^{{t}_{3}} x1 \cdot x2 \cdot x3 \cdot {x}^{′} \partial t ;\end{matrix} \qquad ( 1.15 )$$

where α·\hat{β}·γ is an additional parity of the transmitted data bits α, β and γ, resulting from the multinomial representation of x′. In accordance to an embodiment of the present invention,

$${x}^{′} = sign ( x ) = \frac{1}{2} ( α \cdot x1 + β \cdot x2 + γ \cdot x3 ) - \frac{1}{2} ( α \cdot β \cdot γ \cdot x1 \cdot x2 \cdot x3 ) + N \qquad ( 1.16 )$$

The additional signal from the parity α·\hat{β}·γ in (1.15) is only possible due to the ability to fully derive the multinomial representation of x′=sign(x) with an embodiment of the present invention. By comparing (1.12) and (1.15) we can observe that with the knowledge of the multinomial representation of the hard threshold function sign we can arrive at an improved “hard decision” signal detection scheme.

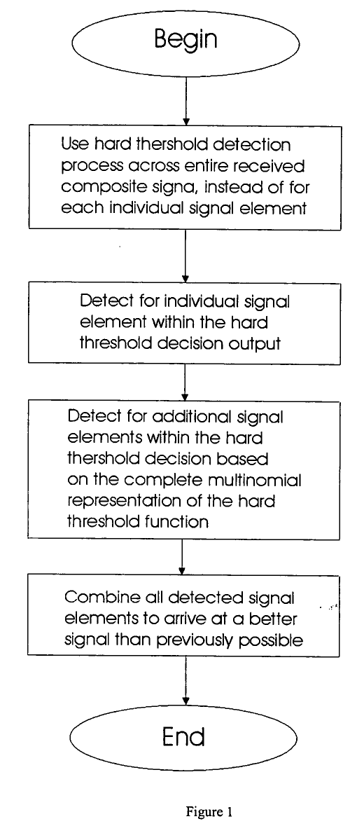

A flow diagram summarizing the current embodiment is given in FIG. 1.

III. An Improved Signals Multiplexing and De-multiplexing Scheme with a Serially Concatenated Iterative Decoding Architecture

An embodiment of the present invention is an improved signals multiplexing and de-multiplexing scheme with a serially concatenated iterative decoding architecture.

In this embodiment of the present invention, the proposed scheme uses a hard threshold sign function at the transmitter equipment to multiplex the data streams from the channel error-correction coding device prior to transmission over the channel. At the receiver equipment, the de-multiplexing process involves a decoding device that is serially concatenated to another channel error correction decoding device. The two decoding devices decode the received data in an iterative manner in an effort to minimize the error in the received data.

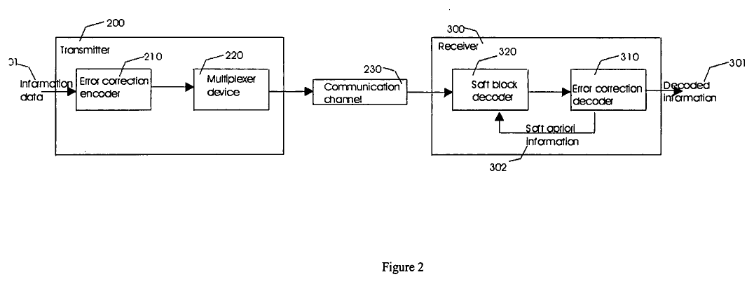

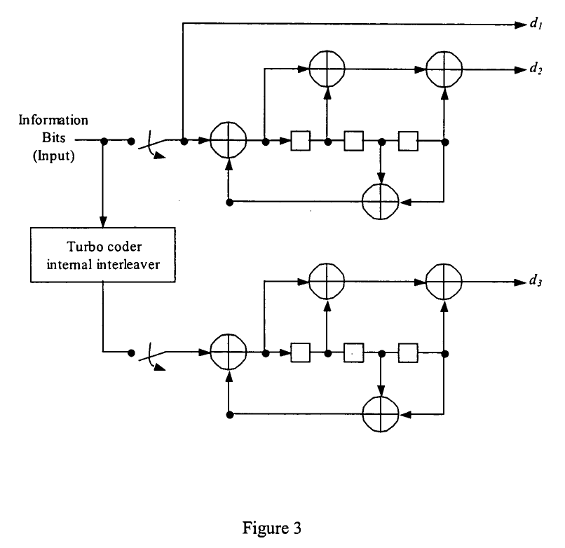

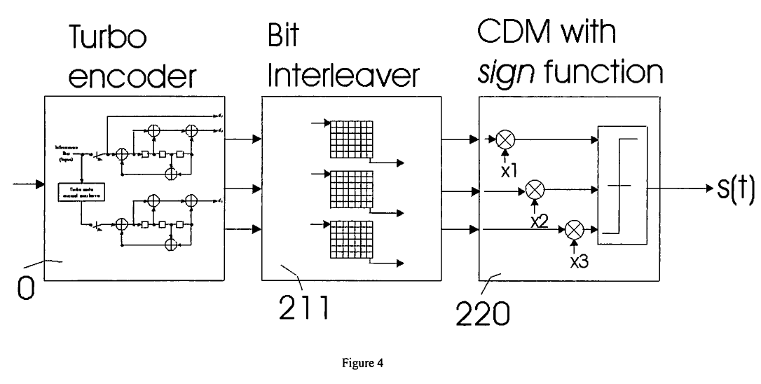

To illustrate this embodiment of the present invention, we refer to the transmitter 200 in FIG. 2. In this figure, the information data 201 is first channel encoded by the channel error correction encoder device 210, and then multiplexed by the multiplexer device 220 before being transmitted into the communication channel 230. At the receiver 300, the received data is decoded in a soft block decoder 320 before further decoded by the channel error correction decoder 310. Both the soft block decoder 320 and channel error correction decoder 310 iteratively decodes and shares soft apriori information 302 between them to further improve the accuracy of the decoded information 301. To better illustrate this embodiment of the present invention, the channel error correction encoder 210 shall be a rate ⅓ Turbo code encoder as depicted in FIG. 3. This channel error correction encoder can use any error correction scheme including, but not limited to, block coding, convolutional coding, Turbo coding and other parity based error correction coding schemes. In the example of FIG. 3, to multiplex the 3 bits, {d1, d2, d3}, of coded data from the Turbo encoder, we use a code division-multiplexing (CDM) scheme together with a sign function. This is depicted in FIG. 4. In FIG. 4, block numbered 211 is a bit interleaver. To multiplex, using multiplexer block number 220, the 3 bits, {d1, d2, d3}, coded information from the Turbo encoder we choose to use 3 orthogonal CDM codes, namely x1, x2 and x3, where

x1=a[1 −1 1 −1];

x2=b[1 1 −1 −1]; (1.17)

x3=c[1 −1 −1 1];

and we used the non-linear hard threshold sign function of (1.1). Together with the multinomial expansion as presented in an embodiment of the present invention, the multiplexed signal s(t) in the proposed example is then

$$\begin{matrix}s ( t ) = sign ( [ \begin{matrix}d1 & d2 & d3\end{matrix} ] [ \begin{matrix}\begin{matrix}x1 \\ x2\end{matrix} \\ x3\end{matrix} ] ) ; \\ = \frac{1}{2} ( d1 \cdot x1 + d2 \cdot x2 + d3 \cdot x3 ) - \frac{1}{2} ( d1 \cdot d2 \cdot d3 \cdot x1 \cdot x2 \cdot x3 ) .\end{matrix} \qquad ( 1.18 )$$

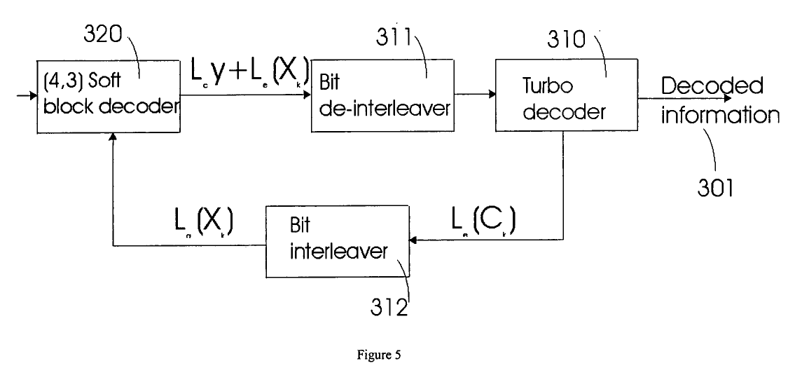

A “priority weighting” scheme can also be assigned for the different data channel at the multiplexing point of the CDM. This is done by giving a priority weight for a,b,c in equation (1.17) according to their importance. The way to calculate this priority weighting is given in the prior art, otherwise all multiplexed channels are set as equal. The multiplexed signal s(t), is then transmitted in the communication channel. At the receiver end, as depicted in FIG. 5, the embodiment of the present invention proposed an innovative approach to the de-multiplexing of the received signal, where the multiplexing process is treated as a coding process. As such, at the receiver, a soft block decoder is used to de-multiplex and decode the multiplexed signal. In the example of FIG. 5, the soft block decoder is numbered 320, and decodes the received signal using a soft block decoding approach similar to the approach described in prior art, which described a soft block decoding process for iterative binary block and convolutional coding. In reference to FIG. 5, assuming for the case where the multiplexer 220 in FIG. 3, multiplexed the d1, d2, d3 interleaved, coded inputs into s(t), where the output after the communication channel y(t)=y1, y2, y3, y4 is a stream of 4 bits spread spectrum outputs. At the receiver 300, as depicted in FIG. 5, these 4 bits spread spectrum outputs is received into a (4,3) soft block decoder, numbered 320 in FIG. 5, constructed according to the general principals as described in the prior art. The output from the (4,3) soft block decoder, numbered 320 in FIG. 5, are logarithmic values L(X₁)L(X₂)L(X₃), where

L(Xₖ)=L_{c}Y+Lₐ(Xₖ)+Lₑ(Xₖ), k∈{1,2,3} (1.19)

and L_{c}y is the logarithmic soft channel value, where

$${L}_{c} y = 4 \frac{{E}_{c}}{{N}_{0}}$$

with E_{c} being energy per transmission chip in s(t) and N₀ being the energy of white gaussian noise. In equation (1.19), Lₐ(Xₖ) is the logarithmic apriori information (numbered 302 in FIG. 4) received from the Turbo decoder (numbered 310 in FIG. 4). In the same equation, Lₑ(Xₖ) is the extrinsic logarithmic information generated by the (4,3) soft block decoder 320. As noted in FIG. 5, the information L(Xₖ) passed onto the bit-wise de-interleaver, numbered 311 in FIG. 5, is stripped of their Lₐ(Xₖ) values as it is the principal of iterative decoding to pass only previously unknown information to a decoding component. The Turbo decoder numbered 310 in FIG. 5, will be engaged in the Turbo decoding process, except that it does not pass out the decoded information 301 at the end of its own internal iterative decoding, unless it is at the completion of both the inner and outer iterative decoding cycle for the block of data received. An inner iterative decoding cycle refers to the iterative decoding cycle within the Turbo decoder and an outer iterative decoding cycle refers to the iterative decoding cycle between the soft block decoder 320 and the Turbo decoder 310. In this example for the embodiment of the present invention, the decoding process involves both the inner and outer cycle iterative decoding, with the final iteration being the inner cycle iteration at the error correction decoder 310. Note, that for other implementations of the present embodiment, where the error correction decoder does not require any iterative decoding, the only cycle of iterative decoding is the outer cycle iterative decoding, where the iteration is between the soft block decoder in 320 and the error correction decoder block in 310.

While not at the completion of both the inner and outer iterative decoding cycles, the Turbo decoder numbered 310 in FIG. 5, will pass out extrinsic logarithmic values of coded bits Lₑ(Cₖ), which include the apriori logarithmic information generated within the Turbo decoder and the extrinsic logarithmic information generated by the Turbo decoder (but not the extrinsic logarithmic information Lₑ(Xₖ) received by the Turbo decoder from the soft block decoder previously) back to the soft block decoder numbered 320. Before passing the extrinsic logarithmic values of coded bits Lₑ(Cₖ) to the soft block decoder 320 (which will view them as apriori logarithmic information Lₐ(Xₖ)), these information bits are passed through a bit-wise interleaver, numbered 312 in FIG. 5, identical to the interleaver block numbered 211 in FIG. 4.

At the soft block decoder, these apriori logarithmic information Lₐ(Xₖ) will be used in the iterative decoding process to generate the next iteration of extrinsic logarithmic information Lₑ(Xₖ) for the next cycle of decoding at the error correction decoder in 310.

At the completion of both the inner and outer iterative decoding cycles, the decoded information (numbered 301) would be outputted from the Turbo decoder (numbered 310).

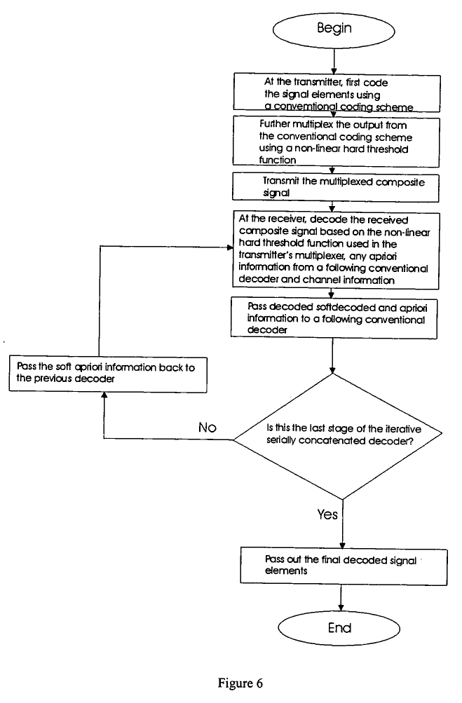

An embodiment of the present invention is in the implementation of a multiplexing process that is also a coding process, which is only possible with the complete multinomial representation of the non-linear hard decision functions introduced in this patent, and to use this implementation in an iterative decoding manner at the receiver, which both accomplishes the tasks of de-multiplexing and providing additional error correction protection in one setting. It is also noted here that in some communication systems, such multiplexing and de-multiplexing schemes are often referred to as channel spreading and de-spreading. As such, the embodiment of the present invention also applies to the use in these channel spreading and de-spreading schemes. A flow diagram summarizing the current embodiment is given in FIG. 6.

IV. Artificial Neural Network Squashing/activation Functions Using a Non-linear Hard threshold Function and its Multinomial Expansion

An embodiment of the present invention is in the use of the non-linear hard threshold functions, such as the sign function or the sign_{±} functions, as the squashing/activation function in artificial neural networks. While, such functions, as the function shown in (1.4), were used as squashing/activation functions in prior arts, their use has since been discarded due to the fact that they are non-differentiable, where being differentiable is an important feature in the learning process of an artificial neural network. In an embodiment of the present invention, the non-linear hard threshold sign_{*} function, as shown in(1.4), with their respective multinomial representation, as described in referenced provisional patent filing, is used as the squashing/activation functions in artificial neural network.

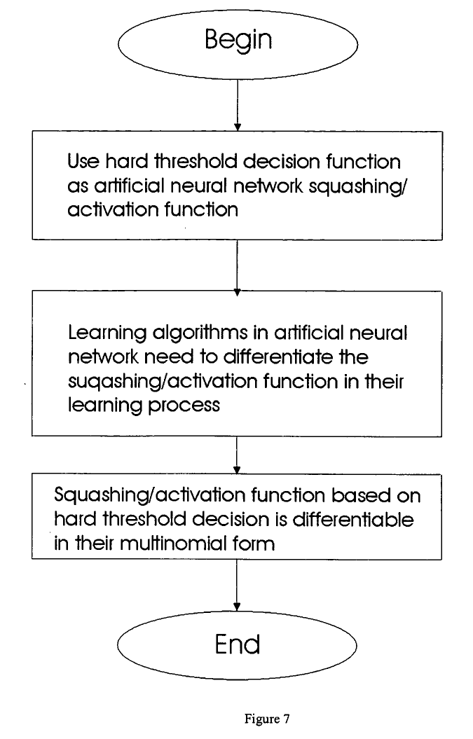

The multinomial expansion of the sign_{*} function as described in an embodiment of the present invention allows these non-linear hard threshold functions to be differentiable, thus, enabling for the learning process in artificial neural networks. This embodiment of the present invention is significant due to the fact that squashing/activation functions using such non-linear hard threshold functions do not introduce the problem of local minima, which otherwise would have existed in artificial neural networks using other squashing/activation functions such as the sigmodial function of (1.5). A flow diagram summarizing the current embodiment is given in FIG. 7.

V. A Novel Combination of Linear and Non-linear Coding and Decoding Functions for Signal Communication

Another embodiment of the present invention is in the use of both linear and non-linear coding functions in the coding and decoding process for a transmission of a composite signal over a transmission link. In this embodiment, linear coding functions are used together with non-linear majority logic coding functions, as the use of such a combination will further enhance the strength of the non-linear majority logic coding functions via the use of linear coding functions. An example of an application of such an embodiment is as illustrated in the referenced provisional patent filing, where linear parity coding is used to code the 3 data streams prior to non-linear majority logic coding. This result in a parallel stream of 8 inputs into the non-linear majority logic coder, namely 3 original parallel data inputs and 5 parity bits derived from these 3 data bits. The output of the non-linear majority logic coder is then transmitted over a communication channel and at the decoder, the received data stream is first majority logic decoded, followed by linear parity decoding. It is shown in that example that the strength of the 8 inputs majority logic coding/decoding scheme is boosted to the equivalence of a 3 inputs majority logic coding/decoding scheme, just by the use of linear parity coding logics.

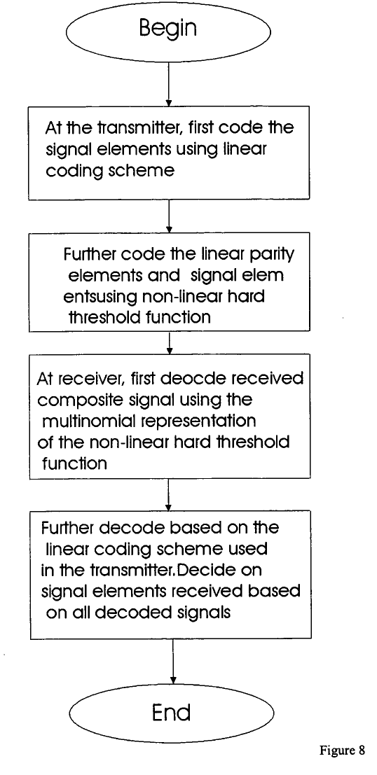

An application of this is in the majority logic coding of 5 parallel input data streams. Prior arts have indicated that this will introduce intrinsic errors, where such errors are due to the coding scheme. This problem can be solved with the current embodiment of the present invention. To solve this problem, we can further derive 3 linear parity logic coded bits from the original 5 data bits. Then, we can use 8 parallel inputs majority logic coding/decoding scheme, which will give us the net coding strength effect of a 5 parallel inputs majority logic coding/decoding scheme, without the problems of intrinsic errors. Examples of linear logic coding schemes and majority logic coding/decoding scheme are well illustrated in the referenced provisional patent filing and other prior arts, and will not be repeated herein. A flow diagram summarizing the current embodiment is given in FIG. 8.

VI. Selection of Multinomial Representation Based on the Non-linear Hard threshold Function Used

As highlighted in the referenced provisional patent filing, the final multinomial representation of the non-linear hard threshold function is depended on the type of non-linear hard threshold function used. This is clearly illustrated in the referenced provisional patent filing and some examples of different multinomial coefficients, ρᵢ, where i={0, 1, 2, 3, . . . , n}, are given in Tables 1 and 2 in the references for the referred provisional patent filing.

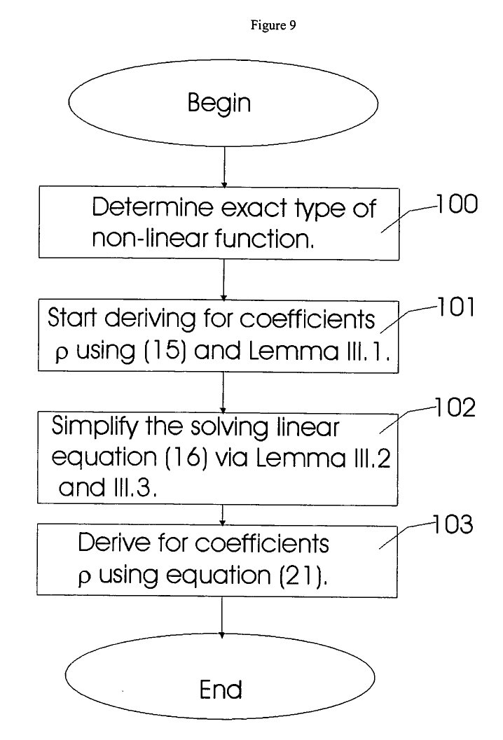

To further summarize, a flow chart on the steps taken to derive the complete multinomial representation of equation (1.10) is presented in FIG. 9. In brief, the derivation of the multinomial representation of equation (1.10) begins with the determination of the exact type of non-linear function represented by equation (1.10)—process 100. Then, we can derive for the coefficients ρ using equation (15) and Lemma III.1 from the cited reference of the referred provisional patent. This is process 101 in FIG. 2. As Lemma III.1 states that the coefficients ρ can be found via solving the linear equation (16) from the cited reference of the referred provisional patent, we shall proceed with Lemma III.2 from the same citation, which was proven with Lemma III.3, also from the same citation. Lemma III.2, together with Lemma III.3, showed us that we could use the involutary property of Rₙ₊₁ to arrive at a simple solution, which allows us to derive for all values for the coefficients of ρ. This is step 102 in FIG. 9. Finally we arrive at step 103, Theorem III.1, which tells us that we can derive for all coefficients ρ by using equation (21) from the cited reference of the referred provisional patent.

While specific embodiments of the present invention have been disclosed, it will be understood by those having ordinary skill in the art that changes may be made to those embodiments without departing from the spirit and scope of the invention. Furthermore, it will be understood that the signals as referenced in the above embodiments encompass signals representations in all applicable domains including, but not restricted to, time signals, frequency signals, sequency signals, phase signals and spatial signals, and all forms of signals representations including, but not restricted to, continuous signals, discrete signals, real signals and imaginary signals. It will be further understood that the mathematical and matrix operations using the multinomial representation of the aforementioned non-linear hard threshold functions, may be implemented in hardware or software. In the latter case, software instructions and data may be embodied in a computer useable medium and stored in a memory of a communications device. The software instructions may include control logic which when executed by a processor or other hardware cause the communications device to encode and decode data messages based on the multinomial representation of the aforementioned non-linear hard threshold functions. When implemented in hardware or firmware, the mathematical and matrix operations using multinomial representation of the aforementioned non-linear hard threshold functions, may be provided by logic on one or more chips or may be burned into, for example, an EEPROM as program instructions and data. It will be further understood that the multinomial representation of the aforementioned non-linear hard threshold functions, may, for retrieval and use by a system, be stored in a memory, embodied in hardware, received from an external source such as other hardware or memory, or derived or generated from stored data or hardware internal to or external to the system.

What is claimed is:

1. A method of hard decision signal detection using the multinomial representation of a non-linear hard threshold function, comprising:
applying the non-linear hard threshold function on a received composite signal to produce an output signal having signal elements;
detecting each signal element within the output based on the multinomial representation of the non-linear hard threshold function used; and
determining the signal elements received based on the detected elements and parity elements derived from the multinomial representation of the non-linear hard threshold function used.

2. A method of multiplexing a stream of coded signals using a non-linear hard threshold function, comprising:
coding signal elements based on one of conventional block, convolution or turbo coding;
multiplexing all the coded signal elements output from the coding based on a non-linear hard threshold function; and
transmitting the multiplexed composite signal in a channel.

3. The method according to claim 2, further comprising decoding the multiplexed composite signal transmitted in claim 2, where the de-multiplexing process is replaced by a soft information decoder operating in a serially concatenated manner with a later stage decoder based on the conventional block, convolution or Turbo decoding scheme.

4. The method according to claim 3, further comprising:
decoding the multiplexed composite signal based on a multinomial representation of the non-linear hard threshold function used and apriori information from the later stage decoder; and
passing out soft decoded information to the later stage conventional block, convolution or Turbo decoder.

5. The method according to claim 4, wherein:
The later stage decoder passes out soft decoded and apriori information back to the decoder, in an iterative manner, until the number of required iterations between the two decoder and the later stage decoder has been completed; and
passing the final decoded information is passed on to the next stage.

6. A method of implementing a squashing/activation function within an artificial neural network based on a non-linear hard threshold function, comprising:
using a complete multinomial representation of a non-linear hard threshold function as a squashing function within an artificial neural network.

7. A method of coding using combined linear and non-linear coding functions, comprising:
deriving parity bits for an uncoded signal;
coding the parity bits based on a linear coding function;
coding the uncoded signal and linear parity bits based on a non-linear hard threshold function; and
transmitting a combined signal based on the coding steps for subsequent linear decoding and non-linear decoding based on a majority logic decoding function.

8. A method of decoding a signal using combined linear and non-linear decoding functions, comprising:
receiving a transmitted signal;
decoding for the parity and uncoded signal bits within the received signal based on a multinomial representation of a non-linear hard threshold function;
further decoding for the uncoded signal bits based on a linear coding function; and
determining the received uncoded signal bits based on information from both the nonlinear and linear decoding processes.

9. A method of optimizing the decoding of a signal, comprising:
decomposing a non-linear function of the sum of binary data into a complete multinomial representation;
determining the coefficients of the multinomial representation;
implementing the multinomial representation, including the coefficients, in majority logic; and
decoding a signal having properties associated with the non-linear function using the majority logic.

10. The method according to claim 9, wherein the non-linear function is a sign_{*} function.

11. The method according to claim 10, wherein the sign_{*} function is a sign function.

12. The method according to claim 10, wherein the sign_{*} function is a sign₋ function.

13. The method according to claim 10, wherein the sign_{*} function is a sign₊ function.

14. The method according to claim 1, wherein the non-linear function is a sigmoidal function.

15. The method according to claim 1, wherein the non-linear function is a sgn function.

16. The method according to claim 10, wherein the multinomial representation is given by equation 3.

17. The method according to claim 16, wherein the coefficients are determined according to equation 8.

18. The method according to claim 16, wherein the coefficients are determined according to equation 21.

19. The method according to claim 16, wherein the coefficients are determined according to equation 22.

20. The method according to claim 16, wherein the coefficients are determined according to equation 23.

21. The method according to claim 9, wherein the signal is coded based on the non-linear function.

22. The method according to claim 21, wherein the coded signal is transmitted within a communications system and decoded at the receiving end of the communication system.

23. A method of coding using combined linear and non-linear coding functions, comprising:
deriving parity bits for a signal;
coding the parity bits based on a linear coding function;
coding the signal and linear parity bits based on a majority logic coding function; and
transmitting a combined signal based on the coding steps for linear decoding and non-linear decoding based on a majority logic decoding function.

24. A method of decoding a signal using combined linear and non-linear decoding functions, comprising:
receiving a signal;
decoding parity bits within the signal based on a majority logic decoding function; and
decoding the signal bits based on a linear coding function.
